(19) United States
(12) Patent Application Publication
(10) Pub. No.: US 2026/0068110 A1
(43) Pub. Date: Mar. 5, 2026

(54) HYBRID ELECTRICAL APPARATUS WITH INTEGRATED THERMAL MANAGEMENT

(71) Applicant: Eaton Intelligent Power Limited, Dublin (IE)

(72) Inventors: Andy Schroedermeier, Whitefish Bay, WI (US); Douglas C. Folts, Baraboo, WI (US)

(73) Assignee: Eaton Intelligent Power Limited, Dublin (IE)

(21) Appl. No.: 19/301,255

(22) Filed: Aug. 15, 2025

Related U.S. Application Data
(60) Provisional application No. 63/684,992, filed on Aug. 20, 2024.

(51) Int. Cl. H05K 7/20

(52) U.S. Cl. CPC H05K 7/20927

(57) ABSTRACT

A tank including an interior; a passive heat management apparatus exterior to the tank and in fluid communication with the interior; an electromagnetic circuit in the interior, the electromagnetic circuit including an input coil assembly and an output coil assembly; and a power converter mounting assembly permanently affixed to and integral with the tank, the power converter mounting assembly including: a first side in the interior, the first side including a heatsink, and a second side not in the interior, the second side including an electronics interface in thermal contact with the heatsink, the electronics interface configured to receive an electronic network including one more heat-generating electronic devices controllable to adjust a property of one or more of a current and a voltage of the electromagnetic circuit. In operational use of the system, the interior includes an electrically insulating fluid, the heatsink is immersed in the electrically insulating fluid, and the electrically insulating fluid transports heat from the electrical network and the electromagnetic circuit.

### CROSS-REFERENCE TO RELATED APPLICATION

This application claims priority to U.S. Provisional Application No. 63/684,992, filed Aug. 20, 2024 and titled HYBRID ELECTRICAL APPARATUS WITH INTEGRATED THERMAL MANAGEMENT, which is incorporated herein by reference in its entirety.

### TECHNICAL FIELD

This disclosure relates to a hybrid electrical apparatus with integrated thermal management.

### BACKGROUND

A voltage regulator is an example of an electrical apparatus. Voltage regulators are used to monitor and control a voltage level in an electrical power distribution network. A voltage regulator includes a main coil and an electromagnetic circuit that delivers current from the main coil to an electric load. The electromagnetic circuit includes electrical contacts, and the main coil includes a plurality of taps. The output voltage of the voltage regulator is determined by which of the plurality of taps are in contact with the electrical contacts. A transformer is another example of an electrical apparatus.

### SUMMARY

In one aspect, a system includes: a tank including an interior; a passive heat management apparatus exterior to the tank and in fluid communication with the interior; an electromagnetic circuit in the interior, the electromagnetic circuit including an input coil assembly and an output coil assembly; and a power converter mounting assembly permanently affixed to and integral with the tank, the power converter mounting assembly including: a first side in the interior, the first side including a heatsink, and a second side not in the interior, the second side including an electronics interface in thermal contact with the heatsink, the electronics interface configured to receive an electronic network including one more heat-generating electronic devices controllable to adjust a property of one or more of a current and a voltage of the electromagnetic circuit. In operational use of the system, the interior includes an electrically insulating fluid, the heatsink is immersed in the electrically insulating fluid, and the electrically insulating fluid transports heat from the electrical network and the electromagnetic circuit.

Implementations may include one or more of the following features.

The tank may include one or more walls that define the interior, and the power converter mounting assembly may be welded or brazed into one or more of the walls.

The heatsink may include a thermally conductive baseplate and thermally conductive fins that extend from the thermally conductive baseplate into the interior.

The electrically insulating fluid may circulate in the interior and the passive heat management apparatus based only on convection.

The power converter mounting assembly may include one or more channels in fluid communication with the interior, and, in operational use, the electrically insulating fluid may pass through the one or more channels. The system also may include a pump in fluid communication with the interior and to the one or more channels. The system also may include: an inlet pipe in fluid communication with an outlet of the pump and a first end of the one or more channels, an outlet pipe in fluid communication with a second end of the one or more channels and the interior, and the pump may be configured to drive the electrically insulating fluid through the one or more channels. The one or more channels may extend upward relative to a bottom of the tank interior.

The tank may include a plurality of walls that surround the interior, the passive heat management apparatus may be on a first one of the plurality of walls, and the power converter mounting assembly may be permanently affixed to and integral with a second one of the plurality of walls. The system also may include a control cabinet attached to the second one of the plurality of walls, and the control cabinet may include a door that, when closed, defines a control interior that encloses the first side of the power converter mounting assembly. The system also may include an input bushing assembly electrically connected to the input coil assembly and an output bushing assembly electrically connected to the output coil assembly, and the input bushing assembly and the output bushing assembly may extend through a third one of the plurality of walls.

The passive heat management apparatus may include one or more conduits, each including an inlet and an outlet in fluid communication with the interior. The one or more conduits may include hollow fin structures. The first side of the power converter mounting assembly may be between the inlet and the outlet of the one or more conduits.

The electronic network may include one or more of a rectifier and an inverter.

In another aspect, a power converter assembly includes: a thermally conductive base portion including a first side and a second side; one or more heat dissipating elements extending from the first side and in thermal contact with the base portion; and an electronics interface on the second side of the thermally conductive base portion and in thermal contact with the thermally conductive base portion, the electronics interface being configured to removably hold a heat-generating electronic element. The thermally conductive base portion is configured for integration into a tank of an electrical apparatus with the first side and the one or more heat dissipating elements in an interior of the tank and in direct contact with an electrically insulating fluid in the interior, and the second side exterior to the tank.

Implementations may include one or more of the following features.

The one or more heat dissipating elements may include fins.

The electronics interface may include one or more channels configured be fluidly coupled to the interior of the tank.

In another aspect, a system includes: a tank including an interior; a passive heat management apparatus exterior to the tank and in fluid communication with the interior; an electromagnetic circuit in the interior, the electromagnetic circuit including an input coil assembly and an output coil assembly; a power converter module including: a thermally conductive plate structure including: a first side, a second side opposite the first side, and a channel that passes through the thermally conductive plate structure; and an electronics interface on the second side, the electronics interface configured to receive an electronic network including one more heat-generating electronic devices controllable to adjust a property of one or more of a current and a voltage of the electromagnetic circuit; and an active fluid moving element in fluid communication with the interior and the channel. In operational use of the system, the interior includes an electrically insulating fluid, and the active fluid moving element causes the electrically insulating fluid to move through the channel to thereby transport heat from the electrical network.

Implementations may include one or more of the following features.

The active fluid moving element may include a pump.

The power converter module may be integrated into a side of the tank with the electronics interface exterior to the tank.

Implementations of any of the techniques described herein may include an electrical enclosure, a voltage regulator, a system, an electrical assembly, or a process. The details of one or more implementations are set forth in the accompanying drawings and the description below. Other features will be apparent from the description and drawings, and from the claims.

### DRAWING DESCRIPTION

FIGS. 1A-1C relate to an example of a hybrid electrical apparatus with integrated thermal management.

FIG. 2 is a schematic of another example of a hybrid electrical apparatus.

FIG. 3 is a schematic of an example of an electronic network.

FIG. 4A is a side view of an example of a power converter module.

FIG. 4B is a top view of the power converter module of FIG. 4A.

FIG. 4C is a front view of the power converter module of FIG. 4A.

FIG. 5A is a perspective exterior view of an example of a three-phase hybrid electrical apparatus.

FIG. 5B is a front view of the three-phase hybrid electrical apparatus of FIG. 5A with the doors opened or removed.

FIG. 5C is a side view of the three-phase hybrid electrical apparatus of FIG. 5A with the control compartment opened.

FIG. 5D is a side view of a wall-like structure that forms a side of the three-phase hybrid electrical apparatus of FIG. 5A.

FIG. 5E shows a power converter integrated into the wall-like structure of FIG. 5D.

FIGS. 6A and 6B show an interior of another example hybrid power apparatus.

FIG. 6C is a side exterior view of a power converter module of the hybrid power apparatus of FIGS. 6A and 6B.

FIG. 6D is an exterior view of an example of an electronic interface.

FIGS. 7A and 7B show an example of an actively cooled hybrid electrical apparatus.

FIGS. 8A and 8B relate to another example of a power converter module.

FIG. 9A is an exterior perspective view of another actively cooled hybrid electrical apparatus.

FIG. 9B shows the interior of the tank of the apparatus of FIG. 9A.

FIG. 9C is an exterior view of a cooling block.

FIG. 10A is an exterior perspective view of an example of a hybrid transformer.

FIG. 10B is a top interior view of the hybrid transformer of FIG. 10A.

FIG. 10C is a side exterior view of the hybrid transformer of FIG. 10A.

### DETAILED DESCRIPTION

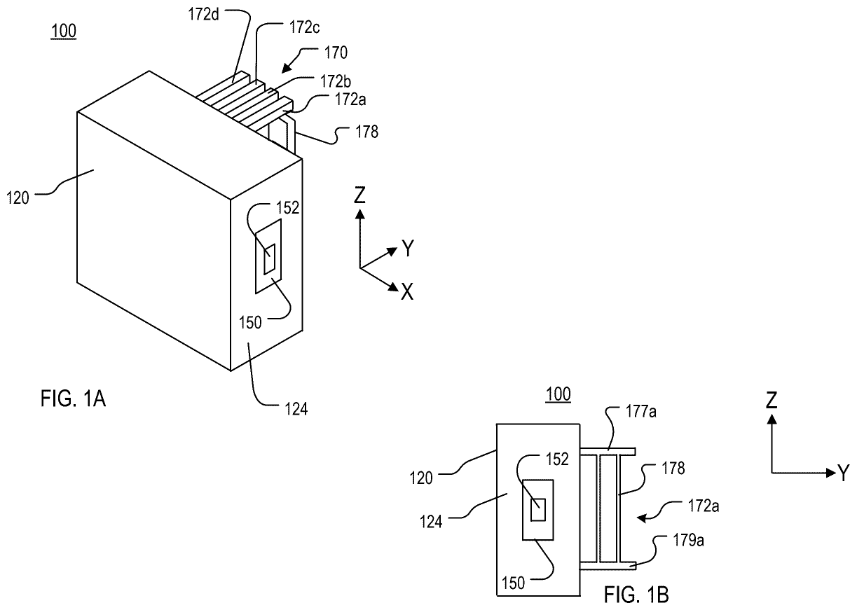

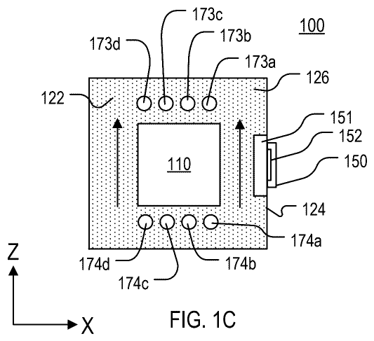

FIGS. 1A-1C relate to a hybrid electrical apparatus 100 with integrated thermal management. The hybrid electrical apparatus includes an electromagnetic circuit 110 and a power converter module 150. The electromagnetic circuit 110 may be, for example, a transformer (for example, a single-phase pole top transformer, a three-phase pad mount transformer, or a station class transformer) or a voltage regulator. The power converter module 150 is controllable to output a current or voltage waveform that has a particular amplitude, frequency, and/or phase. By controlling the characteristics of the output of the power converter module 150, a characteristic of the input and/or the output of the electromagnetic circuit 110 is also controlled. For example, the power converter module 150 may be used to compensate for reactive power, adjust the magnitude of the output voltage and/or current of the electromagnetic circuit 110, adjust the magnitude of the input voltage and/or current of the electromagnetic circuit 110, and/or to reduce harmonic distortion in the output and/or input of the electromagnetic circuit 110.

The power converter module 150 includes an electronic network 152 of devices that generate heat when operated. Examples of heat-generating devices that may be used in the electronic network 152 include semiconductor electronic devices such as power electronics, transistors, thyristors, and diodes, as well as other electronic devices that may or may not include semiconductor materials, such as resistors, inductors, and capacitors. The heat-generating devices may operate at temperatures of, for example, over 100 degrees (°) Celsius (C) (or over 212° Fahrenheit (F)) or over 150° C. (over 302° F.).

Due to the relatively high operating temperatures of these devices, many legacy power converters include a dedicated cooling system that includes fans, blowers, baffles, and/or other objects to direct and/or circulate air or another cooling fluid through the power converter. When these legacy power converters are used with other cooled or thermally managed electrical apparatuses, the complexity of the overall system is increased because there are multiple cooling fluids and cooling systems to control and manage.

On the other hand, the power converter module 150 is cooled with the same cooling fluid (a dielectric fluid 126) as the electromagnetic circuit 110. This approach results in the hybrid electrical apparatus 100 being more compact and simpler to operate than a legacy design in which the power converter is thermally managed by a separate cooling system.

In greater detail, FIG. 1A is an exterior perspective view of the apparatus 100. FIG. 1B is a side exterior view of the apparatus 100. FIG. 1C is a front interior view of the hybrid electrical apparatus 100. The hybrid electrical apparatus 100 includes a tank 120 that defines an interior 122. The electromagnetic circuit 110 and the dielectric fluid 126 (shown with dotted shading) are in the interior 122. The dielectric fluid 126 is any type of electrically insulating and flowable material. For example, the dielectric fluid 126 may be an oil, such as mineral oil or vegetable oil. The fluid 126 may be a transformer fluid or transformer oil. The electromagnetic circuit 110 is immersed in the fluid 126.

The power converter module 150 includes a heatsink 151 that is thermally coupled to the electronic network 152. The power converter module 150 is integrated into a side 124 of the tank 120 with the heatsink 151 extending into the interior 122 of the tank 120 and the electronic network 152 positioned to be accessible from outside of the tank 120. This arrangement allows the fluid 126 to cool the electronic network 152 while also allowing the electronic network 152 to be maintained without disturbing the electromagnetic circuit 110. For example, the electronic network 152 and/or its components may be repaired or replaced without opening the tank 120 and while the electromagnetic circuit 110 continues to operate.

The apparatus 100 also includes a passive thermal management apparatus 170 that is fluidly coupled to the interior 122. Fluid is able to flow between elements that are in fluid communication with each other or that are fluidly coupled to each other. The passive thermal management apparatus 170 may be a radiator. The passive thermal management apparatus 170 includes one or more conduits that are in fluid communication with the interior 122 but extend through the tank 120 such that the conduits are exterior to the tank 120. The conduits are made of a thermally conductive material such as, for example, steel. Four conduits 172a, 172b, 172c, 172d are shown in FIG. 1A, but the passive thermal management apparatus 170 may include more or fewer conduits. Each conduit 172a, 172b, 172c, 172d includes a respective inlet 173a, 173b, 173c, 173d (FIG. 1C) and a respective outlet 174a, 174b, 174c, 174d (FIG. 1C). The inlets 173a, 173b, 173c, 173d and the outlets 174a, 174b, 174c, 174d are in fluid communication with the interior 122. The inlets 173a, 173b, 173c, 173d are above (displaced in the Z direction) the outlets 174a, 174b, 174c, 174d and the power converter module 150 is between the inlets 173a, 173b, 173c, 173d and the outlets 174a, 174b, 174c, 174d.

Referring also to FIG. 1B, which includes a side view of the conduit 172a, the conduit 172a includes a top header pipe 177a, a bottom header pipe 179a, and fin sections 178 (only one of which is labeled in FIG. 1B) that extend between the header pipes 179a and 177a. The interiors of the header pipes 177a and 179a are in fluid communication with the interior of the fin sections 178. The top header pipe 177a is fluidly coupled to the interior 122 of the tank 120 at the inlet 173a, and the bottom header pipe 179a is fluidly coupled to the interior 122 of the tank 120 at the outlet 174a. Thus, fluid in the interior 122 may flow into the header pipe 177a, into the fin sections 178, into the header pipe 179a, and back into the interior 122. The conduits 172b, 172c, 172d are configured in a similar manner with respective top and bottom header pipes and fin sections 178 that extend between the top and bottom header pipes. The passive thermal management apparatus 170 may be configured in other ways. For example, FIG. 1B shows two fin sections 178, but more or fewer fin sections 178 may be used.

In operational use of the apparatus 100, the dielectric fluid 126 is in the interior 122. The temperature of the fluid 126 at full rated load is less than the operating temperature of the electromagnetic circuit 110 and the heat-emitting elements of the electronic network 152. Thus, the fluid 126 heats as the electromagnetic circuit 110 operates and the electronic network 152 rejects heat into the heatsink 151. The heated fluid 126 rises toward the top of the interior 122 (generally in the Z direction in the example shown), carrying heat away from the heatsink 151 and the electromagnetic circuit 110 to thereby cool the electromagnetic circuit 110 and the electronic network 152.

The heated fluid 126 continues to rise, enters the inlets 173a, 173b, 173c, 173d, and then flows into the fin sections 178. Thermal transfer between the fin sections 178 and the air surrounding the apparatus 100 cools the fluid 126. The fluid 126 increases in density as it cools and gravity pulls the fluid 126 downward (generally in the −Z direction) through the fin sections 178 and toward the outlets 174a, 174b, 174c, 174d. The cooled fluid 126 flows out of the outlets 174a, 174b, 174c, 174d and into the bottom of the interior 122. The temperature of the fluid 126 at the bottom of the interior 122 may be, for example, about 5 to 10° C. cooler than at the top of the interior 122. The cycle of heated fluid 126 rising and transporting heat away from the electromagnetic circuit 110 and the heatsink 151 repeats and continues as the hybrid electrical apparatus 100 operates.

In this way, the fluid 126 circulates in the interior 122 of the tank 120, cooling both the electromagnetic circuit 110 and the electronic network 152. Thus, the power converter module 150 is cooled by the fluid 126 and does not include a separate and distinct cooling system. This allows the apparatus 100 to be more compact and more efficient than a hybrid apparatus that includes a separate power converter with a separate dedicated cooling system. Furthermore, the fluid 126 is already part of the hybrid electrical apparatus 100. As such, the integration of the power converter module 150 and the tank 120 also encourages efficient use of materials that are already present in the hybrid electrical apparatus 100.

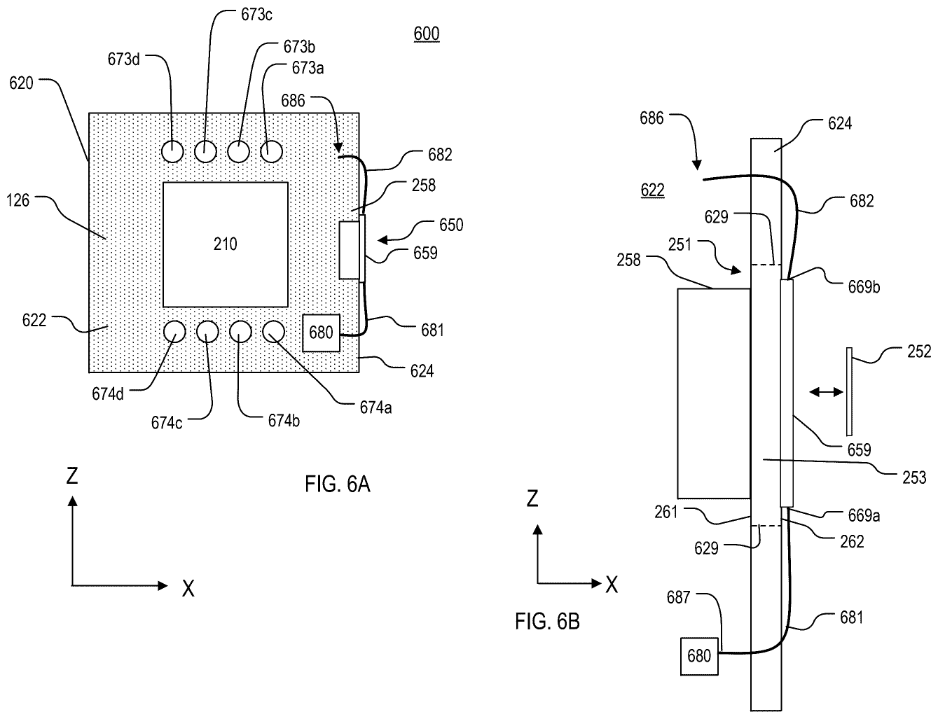

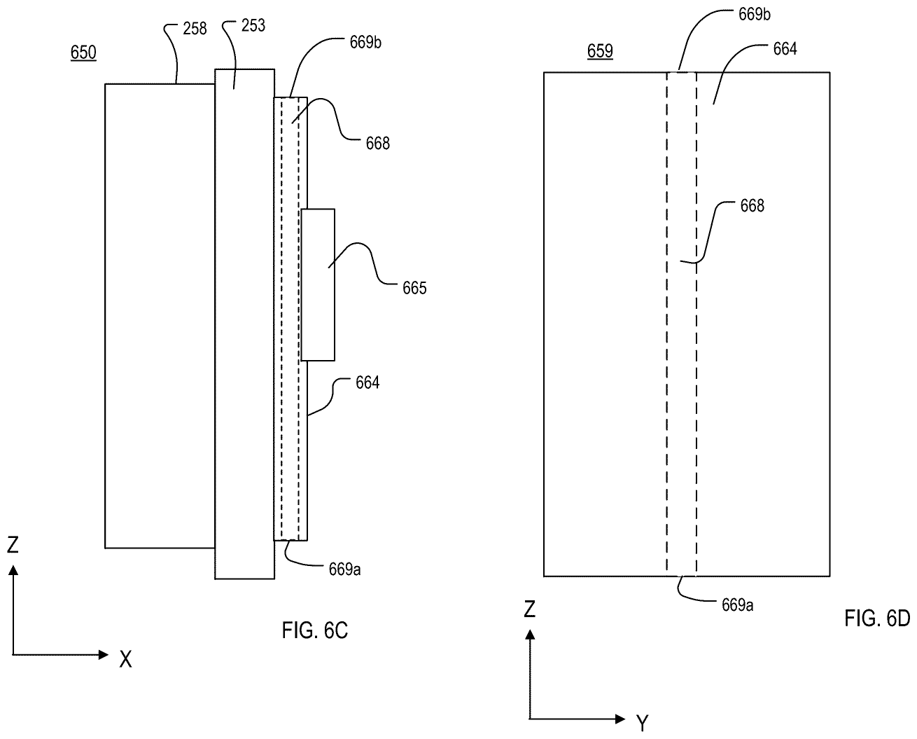

In the hybrid electrical apparatus 100 shown in FIGS. 1A-1C, the thermal management of the electromagnetic circuit 110 and the power converter module 150 is completely passive. However, in some implementations, the apparatus 100 may include active elements to encourage movement of the fluid 126. For example, a fluid pump may be used to encourage the circulation of the fluid 126. FIGS. 6A-6D, 7A, 7B, 8A, 8B, and 9A-9C show examples of active thermal management. Regardless of the specific configuration, the dielectric fluid 126 is used to convey heat away from the electronic network 152 and the electromagnetic circuit 110.

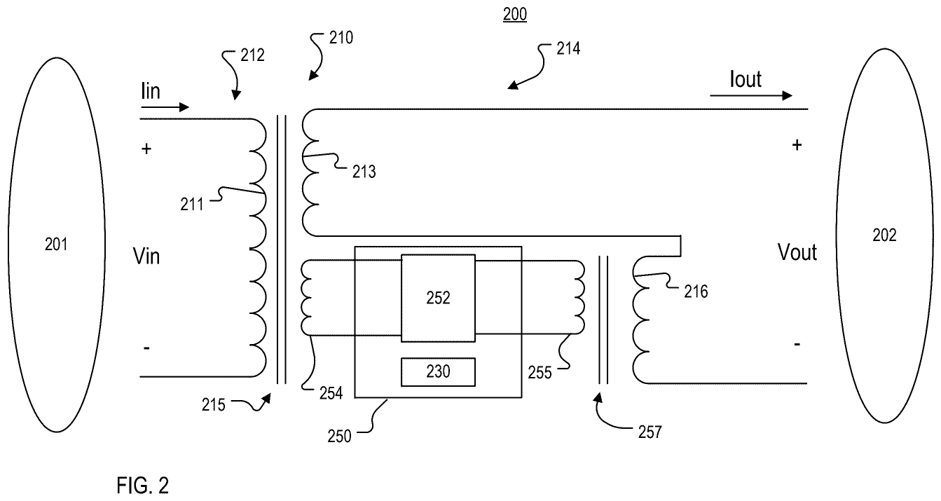

FIG. 2 is a schematic of a hybrid electrical apparatus 200. The hybrid electrical apparatus 200 includes an electromagnetic circuit 210 and a power converter module 250. The hybrid electrical apparatus 200 may be a transformer or a voltage regulator. The electromagnetic circuit 210 includes an input coil assembly 212 and an output coil assembly 214, both of which are made of electrically conductive material, such as copper or another metal. In the implementation shown in FIG. 2, the input coil assembly 212 includes an input winding 211, and the output coil assembly includes an output winding 213 in series with a main injection winding 216.

The input voltage for the electrical apparatus 200 is the voltage across the input coil assembly 212 (Vin), and the output voltage for the electrical apparatus is the voltage across the output coil assembly 214 (Vout). In the implementation shown, the voltage across the input coil assembly 212 is the voltage across the input winding 211, and the voltage across the output coil assembly 214 is the sum of the voltage across the output winding 213 and the voltage across the main injection winding 216. Other configurations are possible. For example, the input coil assembly 212 may include more than one winding.

The hybrid electrical apparatus 200 operates at a voltage appropriate for its application. For example, the voltage at the input terminals (Vin) may be up to 690 volts (V), up to 1 kilovolt (kV), up to 5 kV, up to 35 kV, or between 2 kV and 35 kV. In implementations in which the hybrid electrical apparatus 200 is a transformer, the voltage at the output coil assembly (Vout) may be less than Vin (stepped down) or greater than Vin (stepped up), depending on the configuration of the transformer.

The input coil assembly 212 is electrically connected to a source 201, and the output coil assembly 214 is electrically connected to a load 202. The source 201 is any apparatus or device that produces electricity. The source 201 may be, for example, a generator, a renewable resource or a grid of renewable resources, a distribution station, a three-phase electrical power distribution network that distributes AC electrical power having a fundamental frequency of, for example, 50 or 60 Hertz (Hz), or a node on such a power distribution network. In implementations in which the source 201 is an electrical distribution network, the network may have an operating voltage of up to 690 volts (V), up to kilovolt (kV), 5 kV, or 35 kV and may include, for example, one or more transmission lines, distribution lines, electrical cables, and/or any other mechanism for transmitting electricity. The load 202 is any device that consumes electricity. For example, the load 202 may be a motor, a lighting system, an industrial process (for example, a conveying process or a manufacturing process), or a pumping system.

In some implementations, the source 201 may consume electricity and the load 202 may produce electricity such that electrical power flows through the hybrid electrical apparatus 200 from the output coil assembly 214 to the input coil assembly 212.

The input winding 211 and the output winding 213 are wrapped around a main magnetic core 215. The main magnetic core 215 is made of a ferromagnetic material, such as, for example, iron or steel. The main magnetic core 215 may be a gapped core or an un-gapped core. In implementations in which the core 215 is an un-gapped core, the core 215 is a contiguous segment of ferromagnetic material. A gapped core includes a gap that is not ferromagnetic material. The gap may be, for example, air, nylon, or any other material that is not ferromagnetic.

The input coil assembly 212 and the output coil assembly 214 are electrically isolated from each other but are magnetically coupled to each other via the main magnetic core 215. Through the magnetic coupling, a time-varying electrical current in the input winding 211 generates a time-varying magnetic field in the main magnetic core 215, and the generated time-varying magnetic field induces a corresponding time-varying current in the output winding 213, and vice versa.

The power converter module 250 includes an electronic network 252 and a control system 230 that controls the electronic network 252. In the example shown in FIG. 2, the electronic network 252 is electrically connected to a converter injection winding 255 and an auxiliary winding 254. Each of the auxiliary winding 254 and the converter injection winding 255 is an electrical conductor. For example, each of the auxiliary winding 254 and the converter injection winding 255 may be a wound metal (for example, copper or aluminum) bar or wire. The auxiliary winding 254 is wrapped around the main magnetic core 215 and is thus magnetically coupled to the electromagnetic circuit 210. The converter injection winding 255 is wrapped around an injection core 257, which is a ferromagnetic body. The main injection winding 216 of the output coil assembly 214 is also wrapped around the injection core 257. In this way, the converter injection winding 255 is magnetically coupled to the main injection winding 216.

The power converter 250 may be implemented without the auxiliary winding 254. For example, in applications in which the voltage of the output winding 213 is equal or close to the voltage of the auxiliary winding 254, the input of the power converter module 250 can instead be connected to the output winding 213 thus simplifying construction of electromagnetic circuit 210.

A single phase is shown in FIG. 2. However, the hybrid electrical apparatus 200 may be a multi-phase apparatus. For example, the hybrid electrical apparatus 200 may be a three-phase apparatus that includes an input coil assembly 212, an output coil assembly 214, and injection windings 255 for each of the three phases. In other words, the three-phase hybrid electrical apparatus 200 includes three instances of the input coil assembly 212, three instances of the output coil assembly 214, and three converter injection windings 255. In implementations that include the auxiliary winding 254, the three-phase electrical apparatus 200 also includes three auxiliary windings 254.

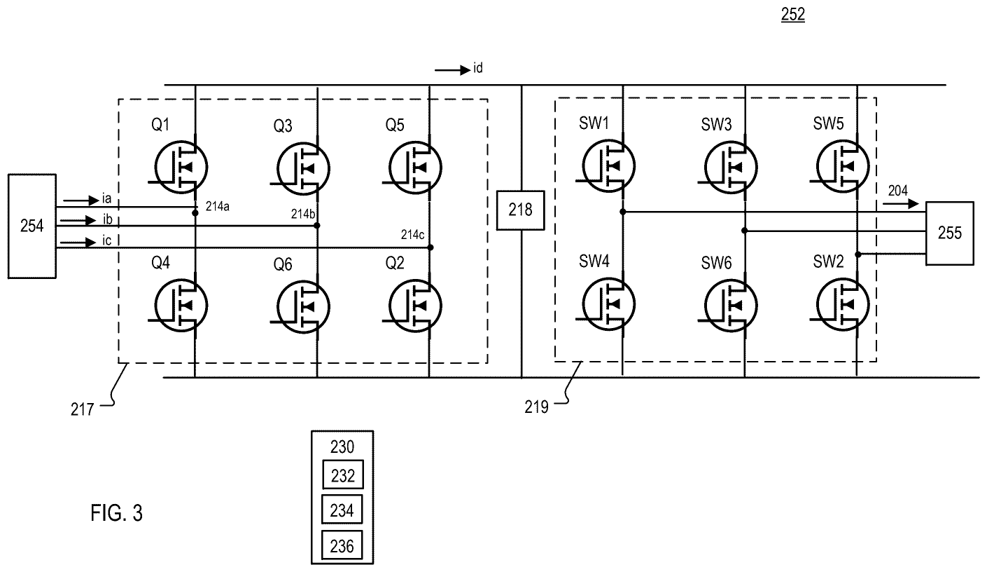

Referring also to FIG. 3, which is a schematic of an example of the electronic network 252, the electronic network 252 includes semiconductor devices such as diodes, thyristors, and/or transistors. In the example shown in FIG. 3, the electronic network 252 is a three-phase back-to-back converter that includes a rectifier 217, a DC link 218, and an inverter 219. The rectifier 217 is a three-phase rectifier that is electrically connected to the auxiliary winding 254 and the inverter 219 that is electrically connected to the converter injection winding 255. In implementations that do not use the auxiliary winding 254, the rectifier 217 is electrically connected to the output winding 213.

The rectifier 217 is a three-phase rectifier that includes six transistors Q1-Q6. In the example shown in FIG. 3, each transistor Q1-Q6 is a metal oxide semiconductor field effect transistors (MOSFET). However, other semiconductor switches may be used in the rectifier 217. For example, each transistor Q1-Q6 may be a silicon carbide (SiC) power MOSFET, an insulated-gate bipolar transistor (IGBT), or bipolar junction transistor (BJT). Moreover, semiconductor devices other than transistors may be used.

The rectifier 217 includes nodes 214a, 214b, 214c, each of which is electrically connected to one phase of the auxiliary winding 254. AC phase currents ia, ib, ic flow in the respective nodes 214a, 214b, 214c. The state of the transistors Q1-Q6 is controlled to rectify the AC input currents ia, ib, ic into a rectified DC current id. The rectified current id flows into the DC link 218 and is stored. The DC link 218 includes any device capable of storing electrical energy. For example, the DC link 218 may include one or more capacitors.

The inverter 219 converts the DC energy stored in the DC link 218 into the injection signal 204. The inverter 219 includes a network of electronic switches SW1-SW6 that are controlled by the control system 230 to generate the injection signal 204. For example, the control system 230 may control the state of the switches SW1-SW6 over time based on a pulse width modulation (PWM) control scheme. Each of the switches SW1-SW6 may be, for example, a power transistor. The three-phase injection signal 204 has phase components 204u, 204v, 204w, each of which may be a voltage or current that is provided to the converter injection winding 255.

The converter injection winding 255 and the main injection winding 216 are wrapped around the injection core 257, and the voltage or current provided to the converter injection winding 255 produces a corresponding voltage or current in the main injection winding 216 via Faraday's law of induction. The control system 230 can control the switches SW1-SW6 to adjust one or more properties of the voltage and/or current at the converter injection winding 255. The adjusted voltage and/or current at the converter injection winding 255 results in a corresponding change in the voltage and/or current at the main injection winding 216. Thus, by controlling the voltage and/or current provided to the injection winding 255, one or more characteristics of the output voltage (Vout) and/or the output current (Iout) of the electromagnetic circuit 210 can be adjusted.

Likewise, the control system 230 can control the switches SW1-SW6 of the rectifier 217 to adjust one or more properties of the AC phase currents ia, ib, ic that flow in the respective nodes 214a, 214b, 214c.

The control system 230 includes an electronic processing module 232, an electronic storage 234, and an input/output (I/O) interface 236. The electronic processing module 232 includes one or more electronic processors. The electronic processors of the module 232 may be any type of electronic processor and may or may not include a general purpose central processing unit (CPU), a graphics processing unit (GPU), a microcontroller, a field-programmable gate array (FPGA), Complex Programmable Logic Device (CPLD), Digital Signal Processor (DSP), and/or an application-specific integrated circuit (ASIC).

The electronic storage 234 may be any type of electronic memory that is capable of storing data and instructions in the form of computer programs or software, and the electronic storage 234 may include volatile and/or non-volatile components. The electronic storage 234 and the processing module 232 are coupled such that the processing module 232 is able to access or read data from and write data to the electronic storage 234. The electronic storage 234 stores instructions that, when executed, cause the electronic processing module 232 to analyze data and/or retrieve information such as intermediate results of computations. Additionally, the electronic storage 234 may store executable instructions that a modulation scheme, such as a PWM modulation scheme, used to control the rectifier 217 and/or the inverter 219.

The I/O interface 236 may be any interface that allows a human operator and/or an autonomous process to interact with the control system 230. The I/O interface 236 also may allow the control system 230 to communicate with components in the apparatus 200 and with systems external to and remote from the apparatus 200.

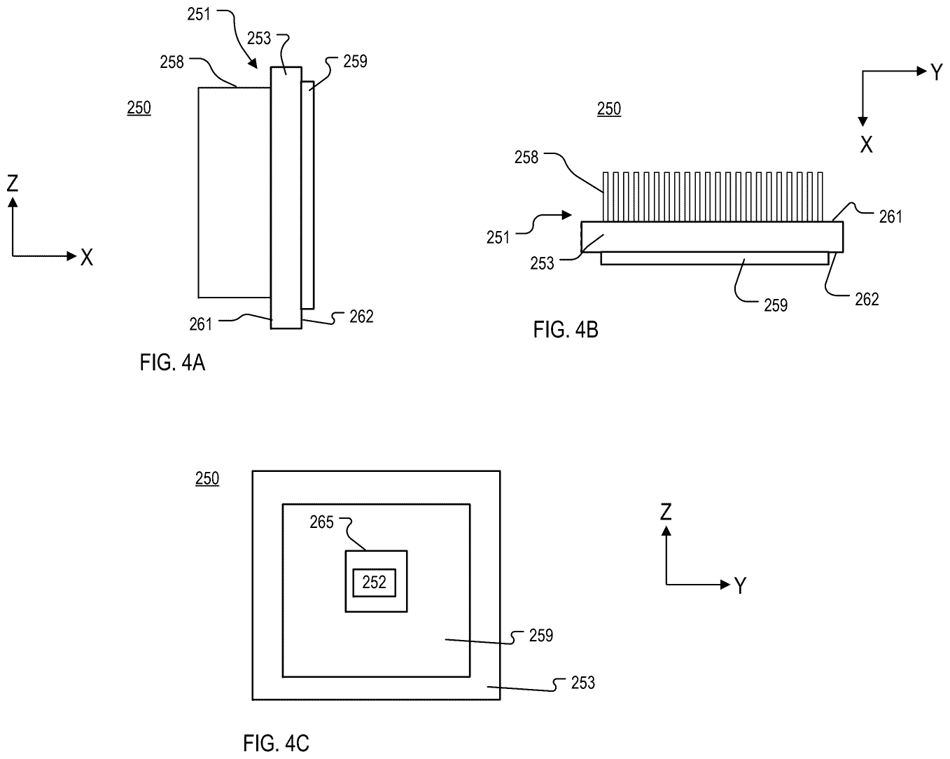

Referring also to FIGS. 4A and 4B, the power converter module 250 includes a heatsink 251 that is thermally coupled to an electronics interface 259. The electronic network 252 is mounted to the electronics interface 259. As shown in FIG. 4A, which is a side view of the power converter module 250, and FIG. 4B, which is a top view of the power converter module 250, the heatsink 251 includes a plurality of fins 258 that extend in the −X direction from a first side 261 of a base portion 253. The fins 258 may be configured in other ways. For example, the fins 258 shown in FIGS. 4A and 4B are planar elements that extend in the X-Z plane. Other implementations are possible. For example, the fins 258 may be arranged on the side 261 to instead extend in the X-Y plane. Moreover, the fins 258 are not necessarily planar.

The fins 258 and the base portion 253 are made of a thermally conductive material that has a relatively high thermal conductivity. For example, the fins 258 and the base portion 253 may be made of a metal, such as copper, steel, or aluminum. The fins 258 and the base portion 253 may be formed as a single piece, or the fins 258 may be attached to the base portion 253 after the base portion 253 is formed. The base portion 253 also includes a second side 262 opposite the first side 261. The electronics interface 259 is attached to the second side 262 of the base portion 253.

Referring also to FIG. 4C, which is a front view of the base portion 253 with the electronic network 252 in the electronics interface 259, the electronics interface 259 is any interface capable of holding the semiconductor devices or other heat-generating devices of the electronic network 252 to the base portion 253 in a removable manner such that the devices of the electronic network 252 can be removed from the electronics interface 259 without damaging the electronics interface 259 or the devices. For example, the electronics interface 259 may include a mounting base, connection assembly, or mounting socket 265.

Regardless of its specific configuration, the electronics interface 259 and the socket 265 are thermally coupled to the base portion 253 such that heat generated during operation of the electronic network 252 is dissipated into the heatsink 251. Moreover, the heatsink 251 may be implemented in other ways. For example, the heatsink 251 may include more or fewer fins 258 than shown in FIGS. 4A and 4B and/or the fins 258 may be shaped and/or arranged other than as shown. Furthermore, the heatsink 251 may be implemented without the fins 258.

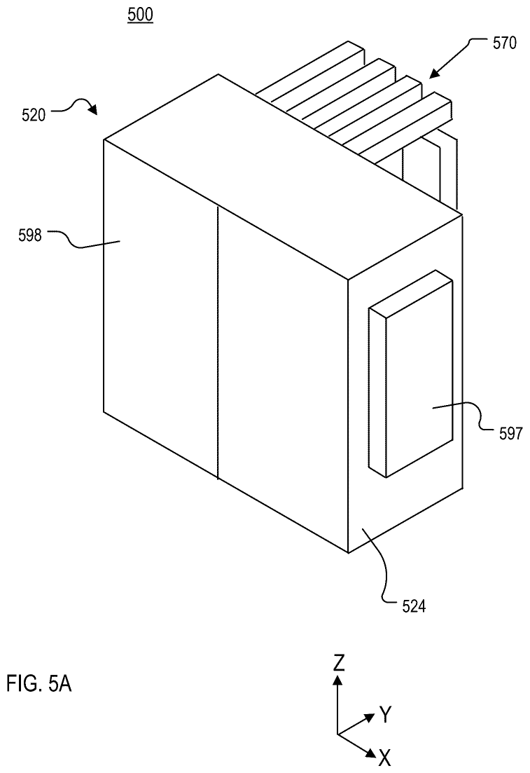

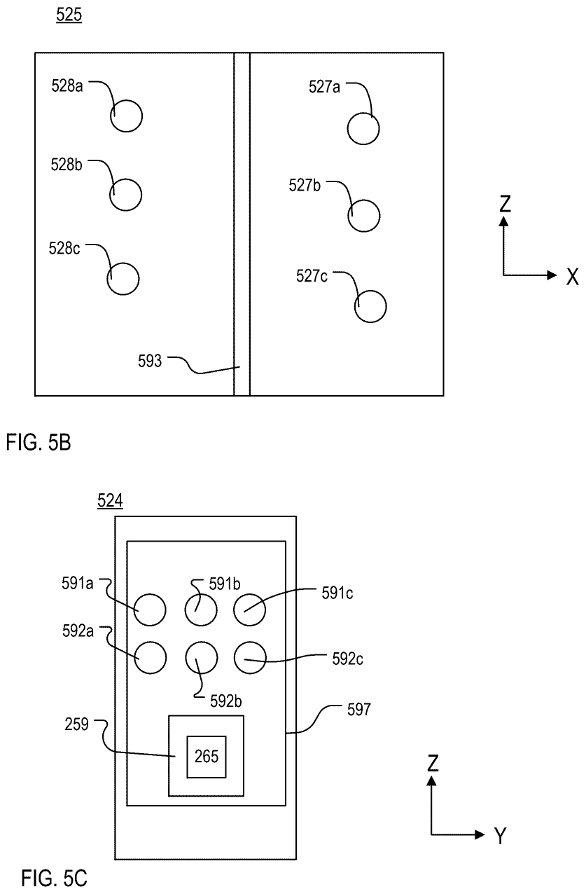

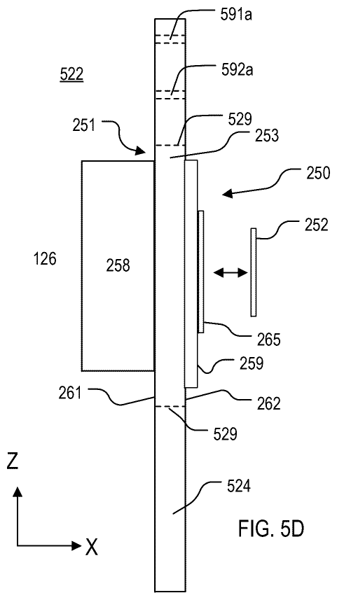

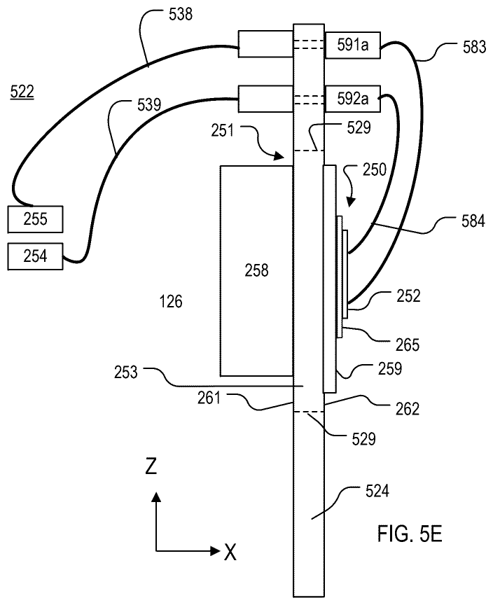

FIGS. 5A-5E relate to a three-phase hybrid electrical apparatus 500 that includes the power converter module 250 and the electromagnetic circuit 210. FIG. 5A is a perspective exterior view of the three-phase hybrid electrical apparatus 500. The apparatus 500 includes a tank 520 and a passive thermal management apparatus 570 that is similar to the passive thermal management apparatus 170 (FIGS. 1A and 1C). The three-phase hybrid electrical apparatus 500 also includes exterior doors 598 and a control compartment 597.

Referring also to FIG. 5B, which is a front view of the three-phase hybrid electrical apparatus 500 with the doors 598 opened or removed, the exterior doors 598 enclose input bushings 528a, 528b, 528c and output bushings 527a, 527b, 527c that extend through a side 525 of the tank 520. The input bushings 528a, 528b, 528c are in a first compartment and the output bushings 527a, 527b, 527c are in a second compartment. The first and second compartments separated by a barrier 593. Depending on the application, the first compartment may be a high-voltage compartment and the second compartment may be a low-voltage compartment, or vice versa. The tank 520 includes an interior 522 (FIG. 5D). The electromagnetic circuit 210 (FIG. 2) and the dielectric fluid 126 are in the interior 522. Each phase of the input coil assembly 212 (FIG. 2) is electrically connected to one of the input bushings 528a, 528b, 528c, and each phase of the output coil assembly 214 (FIG. 2) and the main injection winding 216 are electrically connected to one of the output bushings 527a, 527b, 527c.

Referring again to FIG. 5A, the control compartment 597 is on a side 524 of the tank 520. The control compartment 597 includes a door or cover that encloses the power converter module 250, injection bushings 591a, 591b, 591c, and auxiliary bushings 592a, 592b, 592c. FIG. 5C shows the side 524 with the control compartment 597 opened.

FIG. 5D is a side view of the wall-like structure that forms the side 524 with dashed lines representing hidden elements. The power converter module 250 is integrated into the side 524 such that the base portion 253 forms part of the side 524. For example, during manufacture of the tank 520, the side 524 may be fabricated from a solid sheet or wall of steel or aluminum. To integrate the power converter module 250 into the side 524, an opening is cut in the solid sheet or wall, and the base portion 253 is aligned in the opening with the fins 258 extending into the interior 522 and the electronics interface 259 facing away from the interior 522. The base portion 253 is then secured to the edges 529 (shown with dashed lines in FIG. 5D) of the opening in the sheet or wall. For example, the base portion 253 and the side 524 may be metals that are capable of being welded or brazed together. In these implementations, the base portion 253 is welded or brazed directly to the edges 529 of the opening in the side 524.

Other implementations are possible. For example, the base portion 253 may include flanges that attach to the edges 529 of the opening, and the flanges are fastened to the side 524 to hold the base portion 253 in the side 524. In these implementations, the flanges are also sealed to the side 524 such that the interface between the edges 529 of the opening in the side 524 and the base portion 253 is fluid-tight. Moreover, in the example shown in FIG. 5D, the extent of the base portion 253 in the X direction and the extent of the side 524 in the X direction are substantially the same such that the base portion 253 is flush with the side 524. However, the base portion 253 may have a smaller or larger extent in the X direction compared to the side 524.

FIG. 5E shows the power converter 250 integrated into the side 524 with the electronic network 252 electrically connected to the auxiliary winding 254 and the converter injection winding 255. A cable 583 electrically connects the output of the electrical network 252 to a conductor of the injection bushing 591a. The conductor of the injection bushing 591a is electrically connected to the converter injection winding 255 by a cable 538. A cable 584 electrically connects the input of the electrical network 252 to a conductor of the auxiliary bushing 592a. The conductor of the auxiliary bushing 592a is electrically connected to the auxiliary winding 254 (or to the output winding 213 in implementations that do not include the auxiliary winding 254) by a cable 539. The cable 538, the cable 539, the converter injection winding 255, and the auxiliary winding 254 are in the interior 522. The cables 583 and 584 are exterior to the tank 520. Only one phase is shown in FIG. 5E. The other two phases of the electronic network 252 are connected in a similar manner.

FIGS. 6A-6D, 7A, 7B, 8A, 8B, and 9A-9C show examples of hybrid electrical apparatuses with active thermal management.

FIG. 6A shows an interior 622 of another hybrid power apparatus 600. The hybrid power apparatus 600 includes a tank 620 that defines the interior 622. The interior 622 contains the electromagnetic circuit 210, the dielectric fluid 126, and a fluid pump 680. The apparatus 600 also includes a passive thermal management apparatus that includes inlets 673a-673d and outlets 674a-674d that are in fluid communication with the interior 622.

A power converter module 650 is integrated into a side 624 of the tank 620. The power converter module 650 includes the heatsink 251 and an electronic interface 659 in thermal contact with the heatsink 251. The base portion 253 of the heatsink 251 is welded, brazed, or otherwise sealed into the side 624 at an opening 629. Referring also to FIG. 6C, which is a side exterior view of the power converter module 650, the electronic interface 659 includes sockets or pins 665 on a front exterior side 664. The socket or pins 665 are in thermal contact with the interface 659. The sockets or pins 665 receive and hold the heat-generating electronic components (for example, transistors) of the electronic network 252. The electronic network 252 can be removed from the sockets or pins 665 without damaging the sockets or pins 665 such that the electronic network 252 can be maintained without opening the tank 620 and without disturbing the electromagnetic circuit 210.

Referring also to FIG. 6D, which is an exterior view of the front exterior side 664 of the electronic interface 659 without the socket or pins 665, the electronic interface 659 is a plate-like structure made of a thermally conductive material, such as, for example, steel, copper, or aluminum. A bore or channel 668 passes through the plate-like structure 659 from a first end 669a to a second end 669b. The channel 668 is shown in dotted lines to indicate that it is not visible from the front exterior side 664. Other implementations are possible. For example, the interface 659 may include more than one channel 668 and/or the channel 668 may include curved portions.

Referring again to FIG. 6B, the pump 680 is fluidly coupled to the channel 668. In the example shown, a first end 687 of a first fluid conduit 681 is fluidly coupled to an outlet of the pump 680 and to the first end 669a of the channel 668. The second end 669b of the channel 668 is fluidly coupled to a second fluid conduit 682. Each of the first fluid conduit 681 and the second fluid conduit 682 is any conduit capable of transporting the dielectric fluid 126. For example, the fluid conduits 681 and 682 may be metal pipes or tubes. The fluid conduits 681 and 682 pass through the side 624 and are fluidly sealed to the side 624.

In operational use of the hybrid electrical apparatus 600, the heatsink 251 and the electromagnetic circuit 210 are in the interior 622 and are submerged in the dielectric fluid 126. The pump 680 draws in dielectric fluid 126 and expels it into the fluid conduit 681, driving the fluid 126 through the channel 668 to convey heat away from the electronic network 252. After exiting the second end 669b of the channel 668, heated fluid 126 flows in the second fluid conduit 682 and through an end 686 back into the interior 622. The fluid 126 heated by conveying heat away from the electronic network 252 is cooled via the passive thermal management apparatus. The pump 680 is capable of transporting more heat from electronic network 252 than the heatsink 251 alone. Thus, the active cooling approach offers a solution for higher power applications where the heatsink 251 alone does not transport all or a sufficient amount of heat from the electronic network 252.

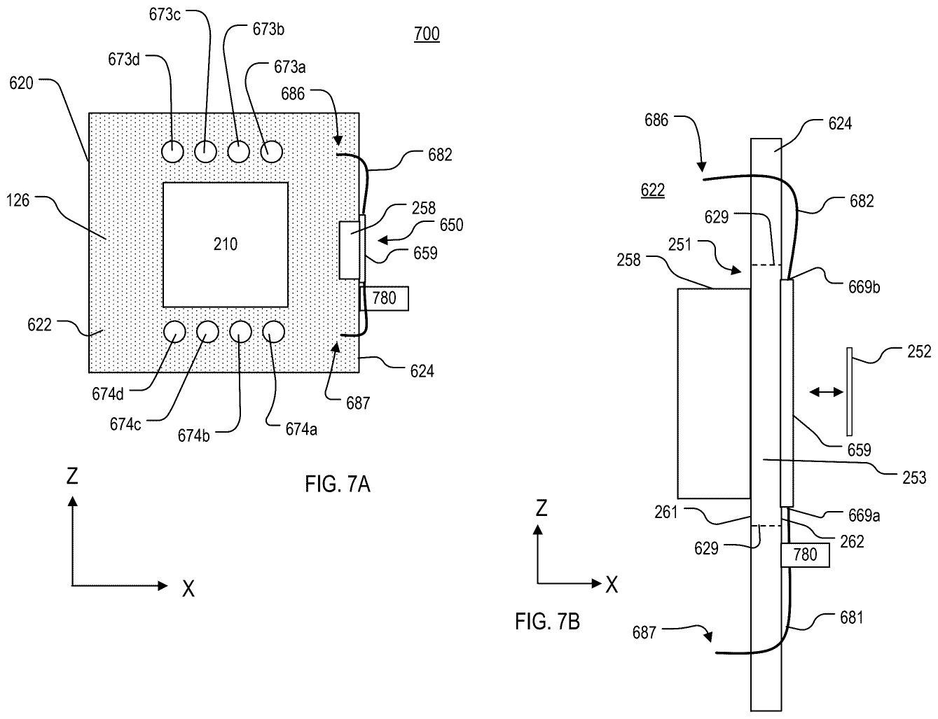

FIGS. 7A and 7B show another actively cooled hybrid electrical apparatus 700 that includes the tank 620, the power converter module 650, and an external fluid pump 780. The apparatus 700 is similar to the apparatus 600, except the external pump 780 is not in the interior 622 of the tank 620. FIG. 7A is a front view of interior 622 of the electrical apparatus 700. FIG. 7B is a side cross-sectional view of the side 624 of the electrical apparatus 700. The first fluid conduit 681 passes through the side 624 of the tank 620 with the first end 687 of the fluid conduit 681 in the interior 622. The external pump 780 is fluidly coupled to a portion of the first fluid conduit 681 that is external to the tank 620.

In operational use, the pump 780 pulls the dielectric fluid 126 into the first fluid conduit 681 through the first end 687 and expels it into the first end 669a of the channel 668. The fluid 126 flows in the channel 668 and conveys heat away from the electronic network 252. The heated fluid 126 exits the channel 668 through the second end 669b, flows through the second fluid conduit 682, and exits the second fluid conduit 682 at the end 686 to re-enter the interior 622 of the tank 620.

The placement of the external fluid pump 780 shown in FIGS. 7A and 7B is provided as an example, and any other placement that fluidly couples the pump 780 to the channel 668 may be used. Moreover, the apparatus 700 may include components in addition to what is shown in FIGS. 7A and 7B. For example, the electrical apparatus 700 may include a control compartment (such as the control compartment 597 shown in FIG. 5A), and the pump 780 may be covered or enclosed by the control compartment.

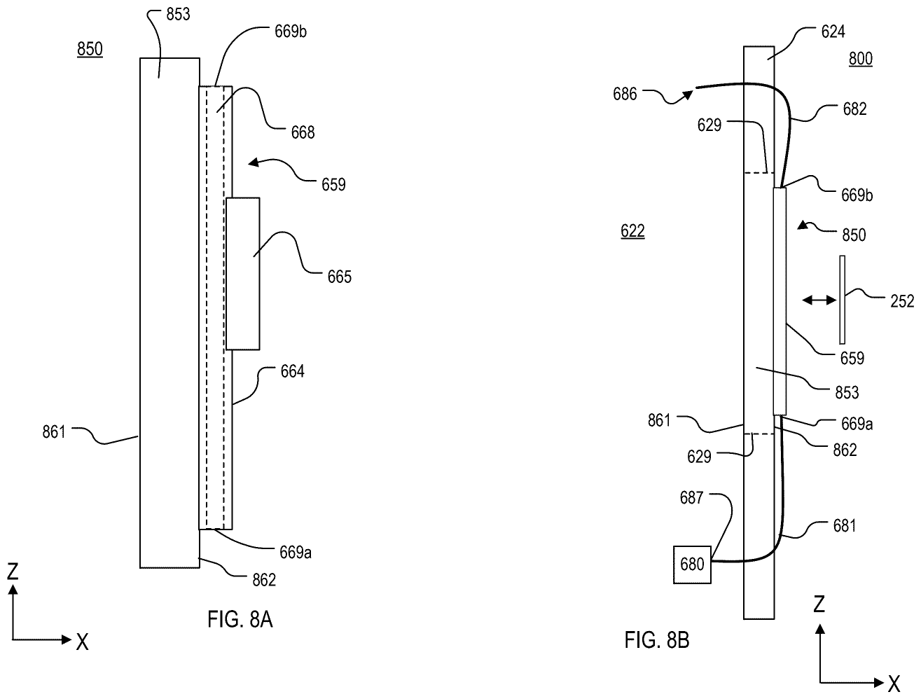

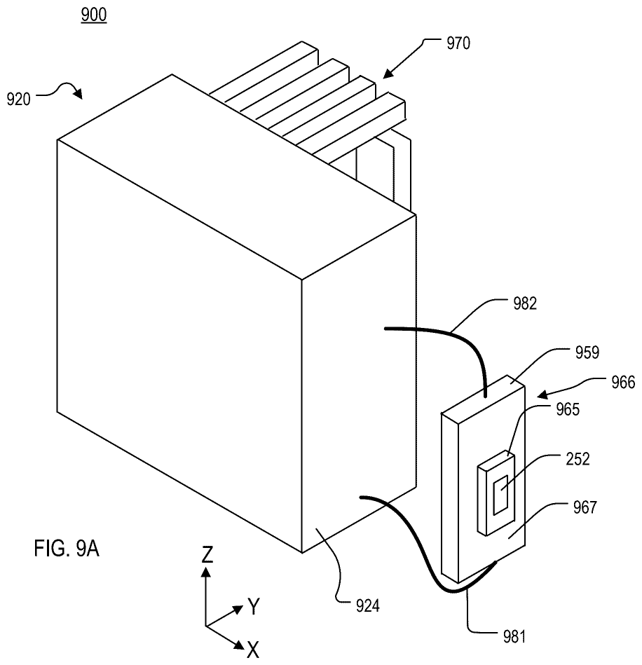

FIGS. 8A and 8B relate to another power converter module 850. FIG. 8A is a side exterior view of the power converter module 850. The power converter module 850 includes a base portion 853 made of a thermally conductive material. The base portion 853 is a plate or wall-like structure. The base portion 853 includes a first side 861 and a second side 862 opposite the first side 861. The interface 659 and socket 665 are on the second side 862 and are in thermal contact with the base portion 853. No fins or other heat dissipating elements extend from the first side 861.

FIG. 8B shows an actively cooled hybrid electrical apparatus 800 that includes the tank 620. The power converter module 850 is integrated into the side 624 of the tank 620. When integrated into the tank 620, the first side 861 of the base portion 853 faces into the interior 622 of the tank 620 and the second side 862 of the base portion 853 is not in the interior 622.

In operational use of the hybrid electrical apparatus 800, the pump 680 draws in dielectric fluid 126 and expels it into the fluid conduit 681, through the first end 669a of the channel 668, and through the channel 668 to convey heat away from the electronic network 252. After exiting the second end 669b of the channel 668, heated fluid 126 flows in the second fluid conduit 682 and back into the interior 622. The fluid 126 heated by conveying heat away from the electronic network 252 is cooled via the passive thermal management apparatus.

Other implementations are possible. For example, the power converter module 850 may be used with an external pump (such as the pump 780) instead of the internal pump 680.

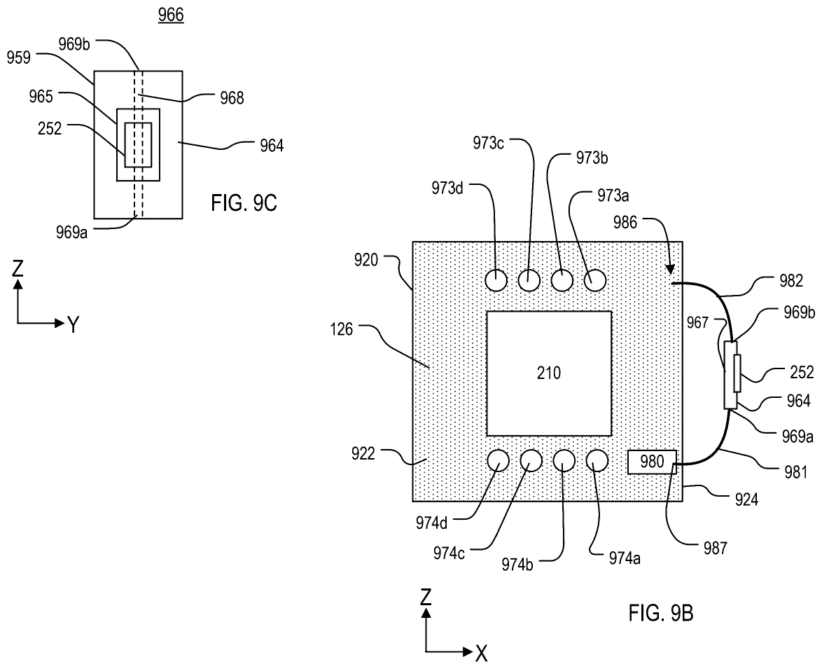

FIG. 9A is an exterior perspective view of another actively cooled hybrid electrical apparatus 900. The electrical apparatus 900 includes a tank 920 and a thermal management apparatus 970. The electrical apparatus 900 does not include an integrated power converter module that forms part of a wall or side of the tank 920. Instead, the electrical apparatus 900 is used with the cooling block 966, which is not integral with the tank 920. Using the discrete cooling block 966 may result in a simpler manufacturing process because the cooling block 966 is not welded or brazed directly into a wall of the tank 920.

FIG. 9B shows an interior 922 of the tank 920. The electromagnetic circuit 210 and the dielectric fluid 126 are in the interior 922. The thermal management apparatus 970 is fluidly coupled to the interior 922 via inlets 973a, 973b, 973c, 973d and outlets 974a, 974b, 974c, 974d.

Referring also to FIG. 9C, which is an exterior view of the cooling block 966, the cooling block 966 includes a cooling plate 959 and a socket 965 that receives the electronic network 252. The socket 965 is any type of interface that holds the electronic network 252 while also allowing the electronic network 252 to be removed for repair or replacement. The socket 965 may be, for example, a pin socket or other interface capable of holding power electronic elements such as transistors.

The cooling plate 959 is a plate or other structure made of any material that has a relatively high thermal conductivity such as, for example, copper or aluminum. The cooling plate has a front exterior surface 964 and a back exterior surface 967 opposite the front exterior surface 964. The socket 965 is on the front exterior surface 964 and is in thermal contact with the cooling plate 959 such that heat generated by the electronic network 252 flows into the cooling plate 959. A channel 968 (shown with dashed lines to indicate that the channel is not visible when viewing the exterior of the front surface 964) passes through the cooling plate 959 from a first end 969a to a second end 969b.

Referring again to FIG. 9B, the first end 969a of the channel 968 is fluidly coupled to a first conduit 981 and the second end 969b of the channel 968 is fluidly coupled to a second conduit 982. In the example shown, each of the first conduit 981 and the second conduit 982 passes through a side 924 of the tank and into the interior 922 of the tank 920. An end 987 of the first conduit 981 is fluidly coupled to an outlet of a pump 980 in the interior 922. An end 986 of the second conduit 982 is in the interior 922.

In operational use, the pump 980 draws in dielectric fluid 126 and expels it into the first conduit 981, into the channel 968 where the fluid 126 carries heat away from the electronic network 252, into the second conduit 982, and back into the interior 922 of the tank 920.

Other configurations are possible. For example, the back exterior surface 967 of the cooling plate 959 may be directly attached to an exterior wall of the tank 920 without being integrated into any of the sides or walls of the tank 920. In another example, the cooling block 966 may be placed in an enclosure and the enclosure may be mounted to the exterior of the tank 920. Moreover, the apparatus 900 may include additional elements that are not shown, such as bushings, doors, and/or compartments.

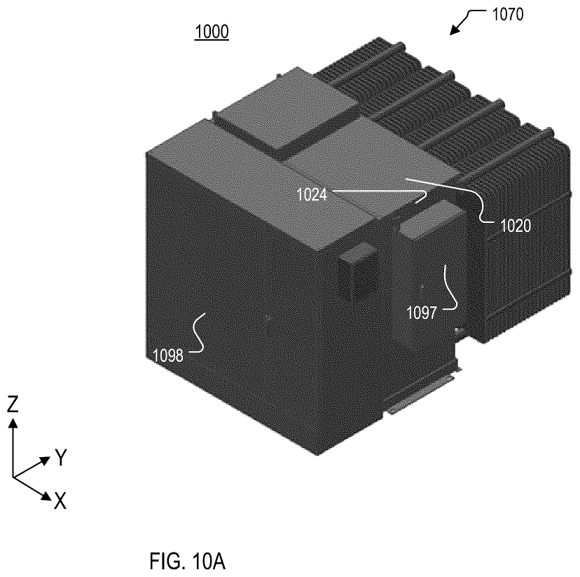

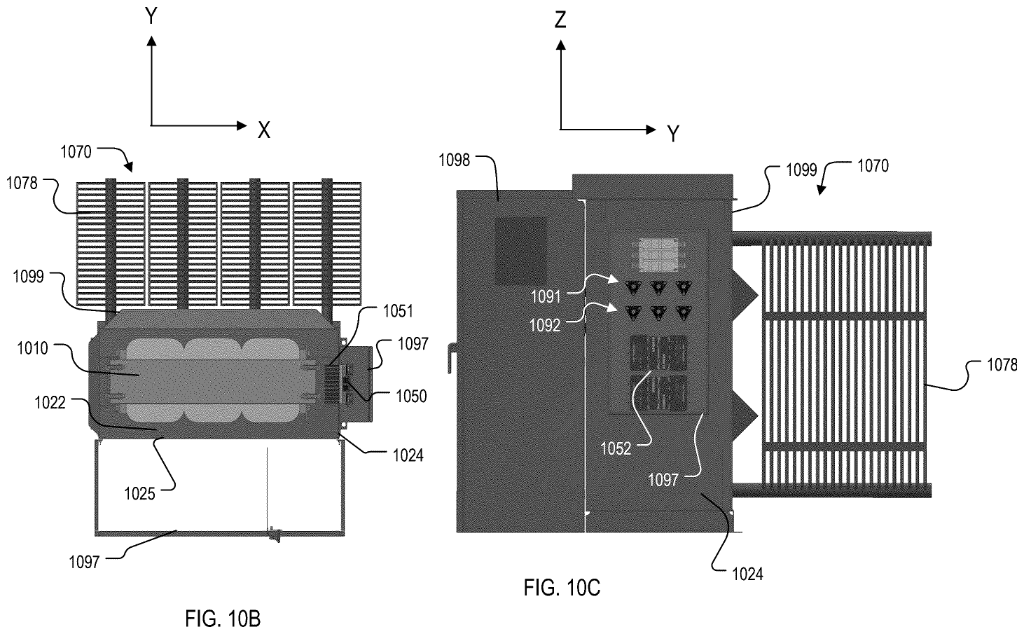

FIG. 10A is an exterior perspective view of a hybrid transformer 1000. FIG. 10B is a top interior view of the hybrid transformer 1000, and FIG. 10C is a side exterior view of the hybrid transformer 1000. The hybrid transformer 1000 includes a tank 1020, a power electronics and control compartment 1097 attached to a side 1024 of the tank, a connection interface compartment 1098 attached to a side 1025 of the tank 1020, and a passive thermal management apparatus 1070 that extends through a side 1099 of the tank 1020. The tank 1020 defines an interior 1022 that contains a three-phase electromagnetic circuit 1010 and dielectric fluid (not shown). The passive thermal management apparatus 1070 includes a plurality of hollow fins 1078 that are outside the tank 1020 and are fluidly coupled to the interior 1022.

The hybrid transformer 1000 also includes a power converter module 1050 that is integrated into the side 1024 and electro-magnetically coupled to the electromagnetic circuit 1010. The power converter module 1050 is used to adjust and/or control one or more properties of an input and/or output of the hybrid transformer 1000. The power converter module 1050 includes a heatsink 1051 that is in the interior 1022 and is thermally coupled to an electronic network 1052.

The electronic network 1052 includes heat-generating electronic devices, such as, for example, power electronics, transistors, diodes, and/or thyristors. The electronic network 1052 is electrically connected to bushings 1091 and 1092. The bushings 1091 are electrically connected to an auxiliary winding or a main winding (not shown) in the interior 1022, and the bushings 1092 are electrically connected to an injection winding (not shown) in the interior 1022.

The electronic network 1052 is not in the interior 1022 and may be accessed through the power electronics and control compartment 1097. The power electronics and control compartment 1097 includes a door that, when closed, encloses the electronic network 1052 and protects it from the environment and tampering. However, the door may be opened by qualified personnel to repair and/or replace the electronic network 1052 and/or components in the electronic network 1052.

In operational use of the hybrid transformer 1000, the heatsink 1051 and the electromagnetic circuit 1010 are submerged in the dielectric fluid. The electromagnetic circuit 1010 and heat expelled by the heatsink 1051 heats the dielectric fluid and the fluid rises in the tank 1020. The heated dielectric fluid enters the passive thermal management system 1070 and is passively cooled in the fins 1078 that are external to the tank 1020, and the cooled dielectric fluid re-enters the tank 1020 near the bottom of the tank 1020. This circulation carries heat away from the electromagnetic circuit 1010 and the heatsink 1051 and aids in the thermal management of the electromagnetic circuit 1010 and the electronic network 1052.

These and other implementations are within the scope of the claims. For example, the tanks 120, 520, 620, 920, and 1020 are shown as having substantially planar walls. However, other implementations are possible. For example, the tank may be cylindrical. Moreover, the power converter module may be integrated into a portion of the tank that is not planar. For example, the power converter module may be integrated into a cylindrical tank or at the interface between two planar sidewalls.

Moreover, the passive thermal management apparatuses 170, 570, 970, and 1070 may be implemented in other ways. For example, the passive thermal management apparatuses 170, 570, 1070 may include more or fewer inlets and outlets, may be different shapes, and may or may not be connected to each other outside of the respective tank. The passive thermal management apparatuses 170, 570, 970, 1070 may be implemented in any manner that allows heat in the dielectric fluid 126 to be rejected to the environment exterior the tank in a passive manner. For example, the individual fins of fin sections 178 may be incorporated directly into one or more walls of the tank 120 with the interiors of the fin sections 178 in fluid communication with the interior 122 of the tank 120. Such a configuration allows the fluid 126 to flow directly into the interiors of the fin sections 178 and may provide a simpler design by eliminating the conduits 172 and header pipes 177 and 179.

What is claimed is:

1. A system comprising:
a tank comprising an interior;
a passive heat management apparatus exterior to the tank and in fluid communication with the interior;
an electromagnetic circuit in the interior, the electromagnetic circuit comprising an input coil assembly and an output coil assembly; and
a power converter mounting assembly permanently affixed to and integral with the tank, the power converter mounting assembly comprising:
a first side in the interior, the first side comprising a heatsink, and
a second side not in the interior, the second side comprising an electronics interface in thermal contact with the heatsink, the electronics interface configured to receive an electronic network comprising one more heat-generating electronic devices controllable to adjust a property of one or more of a current and a voltage of the electromagnetic circuit;
wherein, in operational use of the system, the interior includes an electrically insulating fluid, the heatsink is immersed in the electrically insulating fluid, and the electrically insulating fluid transports heat from the electrical network and the electromagnetic circuit.

2. The system of claim 1, wherein the tank comprises one or more walls that define the interior, and the power converter mounting assembly is welded or brazed into one or more of the walls.

3. The system of claim 1, wherein the heatsink comprises a thermally conductive baseplate and thermally conductive fins that extend from the thermally conductive baseplate into the interior.

4. The system of claim 1, wherein the electrically insulating fluid circulates in the interior and the passive heat management apparatus based only on convection.

5. The system of claim 1, wherein the power converter mounting assembly comprises one or more channels in fluid communication with the interior, and wherein, in operational use, the electrically insulating fluid passes through the one or more channels.

6. The system of claim 5, further comprising a pump in fluid communication with the interior and to the one or more channels.

7. The system of claim 6, further comprising an inlet pipe in fluid communication with an outlet of the pump and a first end of the one or more channels, an outlet pipe in fluid communication with a second end of the one or more channels and the interior, and wherein the pump is configured to drive the electrically insulating fluid through the one or more channels.

8. The system of claim 7, wherein the one or more channels extend upward relative to a bottom of the tank interior.

9. The system of claim 1, wherein the tank comprises a plurality of walls that surround the interior, the passive heat management apparatus is on a first one of the plurality of walls, and the power converter mounting assembly is permanently affixed to and integral with a second one of the plurality of walls.

10. The system of claim 8, further comprising a control cabinet attached to the second one of the plurality of walls, the control cabinet comprising a door that, when closed, defines a control interior that encloses the first side of the power converter mounting assembly.

11. The system of claim 10, further comprising an input bushing assembly electrically connected to the input coil assembly and an output bushing assembly electrically connected to the output coil assembly, wherein the input bushing assembly and the output bushing assembly extend through a third one of the plurality of walls.

12. The system of claim 1, wherein the passive heat management apparatus comprises one or more conduits, each comprising an inlet and an outlet in fluid communication with the interior.

13. The system of claim 12, wherein the one or more conduits comprise hollow fin structures.

14. The system of claim 12, wherein the first side of the power converter mounting assembly is between the inlet and the outlet of the one or more conduits.

15. The system of claim 1, wherein the electronic network comprises one or more of a rectifier and an inverter.

16. A power converter assembly comprising:
thermally conductive base portion comprising a first side and a second side;
one or more heat dissipating elements extending from the first side and in thermal contact with the base portion; and
an electronics interface on the second side of the thermally conductive base portion and in thermal contact with the thermally conductive base portion, the electronics interface being configured to removably hold a heat-generating electronic element, wherein
the thermally conductive base portion is configured for integration into a tank of an electrical apparatus with the first side and the one or more heat dissipating elements in an interior of the tank and in direct contact with an electrically insulating fluid in the interior, and the second side exterior to the tank.

17. The power converter assembly of claim 16, wherein the one or more heat dissipating elements comprise fins.

18. The power converter assembly of claim 16, wherein the electronics interface comprises one or more channels configured be fluidly coupled to the interior of the tank.

19. A system comprising:
a tank comprising an interior;
a passive heat management apparatus exterior to the tank and in fluid communication with the interior;
an electromagnetic circuit in the interior, the electromagnetic circuit comprising an input coil assembly and an output coil assembly;
a power converter module comprising:
a thermally conductive plate structure comprising: a first side, a second side opposite the first side, and a channel that passes through the thermally conductive plate structure; and
an electronics interface on the second side, the electronics interface configured to receive an electronic network comprising one more heat-generating electronic devices controllable to adjust a property of one or more of a current and a voltage of the electromagnetic circuit; and
an active fluid moving element in fluid communication with the interior and the channel, wherein, in operational use of the system, the interior includes an electrically insulating fluid, and the active fluid moving element causes the electrically insulating fluid to move through the channel to thereby transport heat from the electrical network.

20. The system of claim 19, wherein the active fluid moving element comprises a pump.

21. The system of claim 19, wherein the power converter module is integrated into a side of the tank with the electronics interface exterior to the tank.
